(19) United States
(12) Patent Application Publication
(10) Pub. No.: US 2012/0133018 A1
(43) Pub. Date: May 31, 2012

(54) SEMICONDUCTOR DEVICE AND METHOD OF REPAIRING THE SAME

(75) Inventor: Dong Min LEE, Icheon (KR)

(73) Assignee: Hynix Semiconductor Inc., Icheon (KR)

(21) Appl. No.: 13/182,180

(22) Filed: Jul. 13, 2011

(30) Foreign Application Priority Data
Nov. 26, 2010 (KR) 10-2010-0119199

(51) Int. Cl. H01L 23/525

(52) U.S. Cl. 257/529; 257/E23.149

(57) ABSTRACT

A method of repairing a semiconductor device includes forming a first conductive interconnection and a second conductive interconnection spaced from the first conductive interconnection on a semiconductor substrate, forming a magnetic fuse on the first conductive interconnection and forming a first contact plug on the second conductive interconnection, forming a metal interconnection on the magnetic fuse and the first contact plug, and applying a bias to the first conductive interconnection or to the second conductive interconnection corresponding to a normal cell or a redundancy cell and the metal interconnection. The method can readily prevent the problems caused in a laser cutting method without using a method of physically cutting a fuse by radiation of a laser when a semiconductor device fuse is repaired.

### CROSS-REFERENCES TO RELATED APPLICATION

The present application claims priority to Korean patent application number 10-2010-119199, filed on 26 Nov. 2010, which is incorporated by reference in its entirety.

### BACKGROUND OF THE INVENTION

1. Technical Field

The present invention relates to a semiconductor device and a method of manufacturing the same, and more particularly, to a semiconductor device having a magnetic fuse and a method of repairing the same.

2. Related Art

Semiconductor devices, like memory devices and memory merged logic (MML) devices, include numerous memory cells for storing data. However, when any one of the memory cells fails, the semiconductor device also fails, and yield is decreased. It is not cost-effective to discard the whole device when defects are generated only in a part of cells of the semiconductor device. Hence, in a semiconductor device, a repair function is necessary to increase yield. A semiconductor device employs a method of replacing a defective cell with a redundant cell. A cuttable fuse is used to replace the defective cell with the redundant cell. Accordingly, a plurality of fuses is included in the semiconductor device, and these fuses can be cut by laser. The fuses are selectively cut according to a test result obtained after the semiconductor device is tested.

The repairing method using the redundant cell sets a redundant word line provided to replace a normal word line and a redundant bit line provided to replace a normal bit line in a given cell array. The normal word line or the normal bit line which includes a failed cell are replaced with the redundant word line or the redundant bit line, respectively.

To this end, the memory device includes a circuit for replacing an address corresponding to the failed cell with an address of the redundant cell when the failed cell is chosen through the test after wafer fabrication is completed. Accordingly, when an address signal corresponding to the failed cell is inputted, data of the replaced redundancy cell corresponding to the failed cell is accessed.

The most widely used method among repairing methods is a method of burning a fuse with a laser beam to perform blowing, so that a route of the address is redirected to select the redundant cell. Accordingly, the memory device includes a fuse unit, which can change the address route by irradiating a laser to the fuse. In this description, a fuse refers to a wiring that is cut by the irradiation of a laser, and a fuse box refers to an area surrounding the fuse.

In a process of blowing a fuse to replace an address route, while an insulating layer having a predetermined thickness remains on the fuse, a laser is radiated to the fuse corresponding to a failed cell, thereby cutting the fuse corresponding to the failed cell. However, since the insulating layer has the same property as glass, laser energy just penetrates the insulating layer without being absorbed therein. Thereby, most of the laser energy is absorbed in the fuse and thus the fuse is thermally expanded by the laser energy. As a result, the fuse is blown up and cut. That is, in a blowing process, a fuse blowing unit which receives the laser energy has to be totally evaporated and then floated in the air.

However, when the fuse blowing unit is not totally evaporated, a remaining residue causes both ends of the cut fuse to be connected with each other. Thereby, the fuse to be cut is not completely cut and the address repair process can not be correctly performed. Even when the fuse is cut, since fuse metal migrates under high temperatures and humidity reliability conditions, the fuse may not be correctly cut. Further, a laser affects not only a target fuse itself but a periphery of the target fuse in such a manner that the laser is applied to an undesired portion of the cell, resulting in a failure.

### SUMMARY

The present invention is to provide a semiconductor device and a method of repairing the same when a fuse is cut by applying a laser to repair the semiconductor device, capable of preventing failure caused by a laser applied to an undesired portion or preventing incorrect cutting by migration of a fuse metal under the reliability condition even when the fuse has been cut.

According to one aspect of an exemplary embodiment, a method of repairing a semiconductor device includes forming a first conductive interconnection and a second conductive interconnection spaced from the first conductive interconnection on a semiconductor substrate, forming a magnetic fuse on the first conductive interconnection and forming a contact plug on the second conductive interconnection, forming a metal interconnection on the magnetic fuse and the first contact plug, and applying a bias to the first conductive interconnection or the second conductive interconnection corresponding to a normal cell or a redundancy cell and the metal interconnection.

When the first conductive interconnection is connected to the normal cell, the second conductive interconnection may be connected to the redundancy cell. Alternatively, when the first conductive interconnection is connected to the redundancy cell, the second conductive interconnection may be connected to the normal cell.

The magnetic fuse may include a first material layer having a spin arrangement of a first direction, a barrier layer disposed on the first material layer and a second material layer disposed on the barrier layer and having a spin arrangement of the first direction or a second direction as a reverse direction of the first direction according to the bias.

The bias may include a forward bias or a reverse bias.

The forward bias may cause the second material layer to have the spin arrangement of the first direction.

The forward bias may be applied when the normal cell is a non-failed cell.

The reverse bias may cause the second material layer to have the spin arrangement of the second direction.

The reverse bias may be applied when the normal cell is a failed cell.

The reverse bias may have an opposite polarity to the forward bias.

A bias which is applied to the first or second conductive interconnection may have an opposite polarity to a bias which is applied to the metal interconnection.

The first material layer may include any one selected from the group consisting of IrMn, PtMn, MnO, MnS, MnTe, MnF₂, FeF₂, FeCl₂, FeO, CoCl₂, CoO, NiCl₂ and NiO.

The second material layer may include any one selected from the group consisting of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, MgOFe₂O₃, EuO, Y₃Fe₅O₁₂ and a combination thereof.

The barrier layer may include an insulating layer.

The insulating layer may have a thickness to penetrate electrons.

The first conductive interconnection and the second conductive interconnection may include a bit line.

The method may further include forming a second contact plug on the first conductive interconnection before the forming the magnetic fuse.

According to another aspect of another exemplary embodiment, a semiconductor device includes a first conductive interconnection and a second conductive interconnection that is spaced apart from the first conductive interconnection disposed over a semiconductor substrate; a magnetic fuse disposed over the first conductive interconnection; a contact plug disposed over the second conductive interconnection; and a metal interconnection disposed over the magnetic fuse and the contact plug, wherein the magnetic fuse includes: a first material layer having a spin arrangement in a first direction; a barrier layer disposed over the first material layer; and a second material layer disposed over the barrier layer and having a spin arrangement in the first direction or in a second direction opposite to the first direction, depending on an applied bias.

The applied bias includes a forward bias or a reverse bias.

The forward bias is applied, the second material layer has the spin arrangement in the first direction.

The forward bias is applied when the normal cell is a non-failed cell.

The reverse bias is applied, the second material layer has the spin arrangement in the second direction.

The reverse bias is applied when the normal cell is a failed cell.

The reverse bias has an opposite polarity to the forward bias.

The first material layer may include any one selected from the group consisting of IrMn, PtMn, MnO, MnS, MnTe, MnF₂, FeF₂, FeCl₂, FeO, CoCl₂, CoO, NiCl₂, NiO and a combination thereof.

The second material layer may include any one selected from the group consisting of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, MgOFe₂O₃, EuO, Y₃Fe₅O₁₂ and a combination thereof.

The barrier layer may include an insulating layer and the insulating layer may have a thickness to penetrate electrons.

According to another aspect of another exemplary embodiment, a semiconductor device includes a first conductive interconnection and a second conductive interconnection which are insulated from each other, a magnetic fuse coupled to the first conductive interconnection, a contact plug coupled to the second conductive interconnection and a third conductive interconnection commonly coupled to the magnetic fuse and the contact plug, wherein the magnetic fuse includes a first magnetic layer configured to have a first spin arrangement and a second magnetic layer formed over or below the first magnetic layer and configured to have the first spin arrangement when a forward bias is applied between the first conductive interconnection and the third conductive interconnection, and further configured to have a second spin arrangement different from the first spin arrangement when a reverse bias is applied between the first conductive interconnection and the third conductive interconnection.

At the forward bias, the second magnetic layer is configured to have the first spin arrangement so that the first conductive interconnection and the third conductive interconnection are coupled to each other through the magnetic fuse, and wherein, at the reverse bias, the second magnetic layer is configured to have the second spin arrangement so that the first conductive interconnection and the third conductive interconnection are insulated from each other by the magnetic fuse.

The first magnetic layer includes any one selected from the group consisting of IrMn, PtMn, MnO, MnS, MnTe, MnF₂, FeF₂, FeCl₂, FeO, CoCl₂, COO, NiCl₂, NiO and a combination thereof.

The second magnetic layer includes any one selected from the group consisting of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, MgOFe₂O₃, EuO, Y₃Fe₅O₁₂ and a combination thereof.

The semiconductor device further comprise a barrier layer disposed over the first magnetic layer, wherein the second magnetic layer disposed over the barrier layer.

The barrier layer includes an insulating layer formed to such a thickness that electrons can penetrate the insulating layer.

According to another aspect of another exemplary embodiment, a method of repairing a semiconductor device includes providing a semiconductor device of exemplary embodiment, determining whether there is a failure in the first conductive interconnection, applying a forward (magnetic) bias between the first conductive interconnection and the third conductive interconnection so that the first conductive interconnection and the third conductive interconnection are coupled to each other by the second magnetic layer, in case there is no failure in the first conductive interconnection and applying a reverse (magnetic) bias between the first conductive interconnection and the third conductive interconnection so that the first conductive interconnection and the third conductive interconnection are insulated by the second magnetic layer, and instead, the second conductive interconnection and the third conductive interconnection are coupled to each other, in case there is a failure in the first conductive interconnection.

These and other features, aspects, and embodiments are described below in the section entitled “DESCRIPTION OF EXEMPLARY EMBODIMENT”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a cross-sectional view illustrating a semiconductor device according to an exemplary embodiment of the present invention;

FIG. 2 illustrates a spin arrangement when a forward bias is applied to a semiconductor device fuse according to an exemplary embodiment of the present invention; and

FIG. 3 is a view illustrating a spin arrangement when a reverse bias is applied to a semiconductor device fuse according to an exemplary embodiment of the present invention.

### DESCRIPTION OF EXEMPLARY EMBODIMENT

Exemplary embodiments are described herein with reference to cross-sectional illustrations that are schematic illustrations of exemplary embodiments (and intermediate structures). As such, variations from the shapes of the illustrations that results, for example, from manufacturing techniques and/or tolerances, are to be expected. Thus, exemplary embodiments should not be construed as limited to the particular shapes of regions illustrated herein, but may include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other layer or substrate, or intervening layers may also be present therebetween.

Hereinafter, a semiconductor device and a method of repairing the same according to an exemplary embodiment of the present invention will be described in further detail with reference to the accompanying drawings.

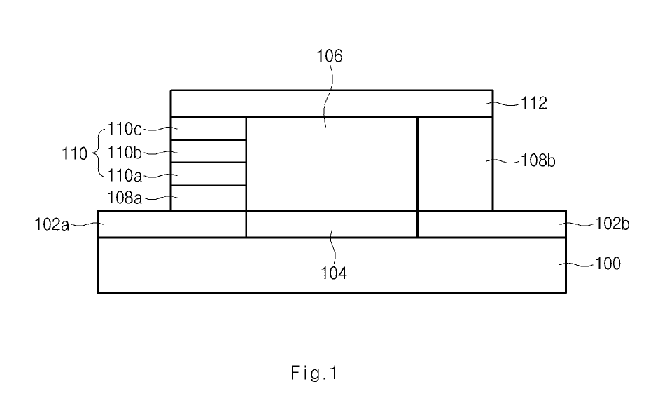

FIG. 1 is a cross-sectional view illustrating a semiconductor device including a fuse according to an exemplary embodiment of the present invention. Referring to FIG. 1, the semiconductor device having a fuse may include a first conductive interconnection 102a and a second conductive interconnection 102b disposed on a semiconductor substrate 100, which are spaced apart from each other, a second contact plug 108a disposed on the first conductive interconnection 102a, a first contact plug 108b disposed on the second conductive interconnection 102b, a magnetic fuse 110 disposed on the second contact plug 108a, and a metal interconnection 112 disposed on the magnetic fuse 110 and the first contact plug 108b.

Here, the semiconductor device may further include a first interlayer insulating layer 104 disposed between the first conductive interconnection 102a and the second conductive interconnection 102b to insulate the first conductive interconnection 102a and the second conductive interconnection 102b from each other. A second interlayer insulating layer 106 is disposed on the first interlayer insulating layer 104 and between the first contact plug 108b and the second contact plug 108a to insulate the first contact plug 108b and the second contact plug 108a from each other. A height of the first contact plug 108b may be equal to a sum of a height of the second contact plug 108a and a height of the magnetic fuse 110. The first conductive interconnection 102a and the second conductive interconnection 102b may include bit lines, respectively. In addition, when the first conductive interconnection 102a is connected to a normal cell, the second conductive interconnection 102b may be connected to a redundancy cell. Alternatively, when the first conductive interconnection 102a is connected to a redundancy cell, the second conductive interconnection 102b may be connected to a normal cell.

The magnetic fuse 110 may include a stack structure of a first material layer 110a, a barrier layer 110b and a second material layer 110c. Here, the first material layer 110a may have a spin arrangement in a first direction and the second material layer 110c may have a spin arrangement in the first direction or in a second direction which is an opposite direction to the first direction, depending on a bias.

The first material layer 110a may include IrMn, PtMn, MnO, MnS, MnTe, MnF₂, FeF₂, FeCl₂, FeO, CoCl₂, CoO, NiCl₂, NiO or a combination thereof and the second material layer 110c may include Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, MgOFe₂O₃, EuO, Y₃Fe₅O₁₂ or a combination thereof. The barrier layer may include an insulating layer. The insulating layer is configured to have a thickness such that electrons can penetrate it.

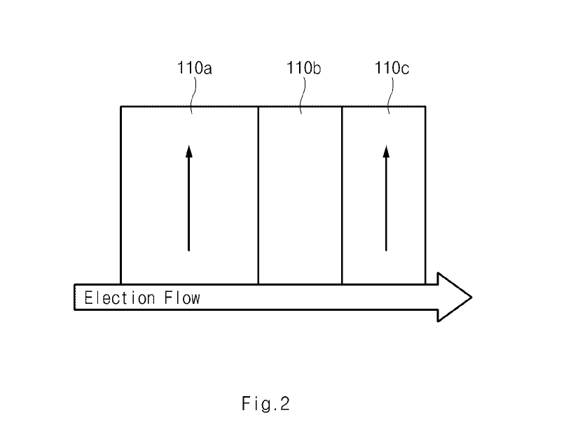

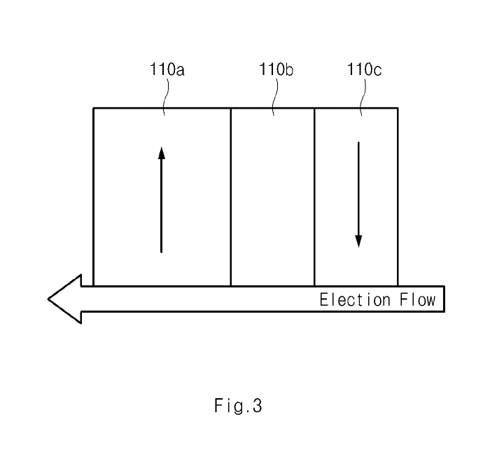

The bias may include a forward bias or a reverse bias. Specifically, a spin direction of a magnetic fuse according to a bias will be described in more detail with reference to FIGS. 2 and 3.

FIG. 2 is a view illustrating a spin direction when a forward bias is applied to a semiconductor device fuse and FIG. 3 is a view illustrating a spin direction when a reverse bias is applied to the semiconductor device fuse.

As shown in FIG. 2, when the forward bias is applied to the magnetic fuse 110, the first material layer 110a has a spin arrangement in a first direction. The second material layer 110c also has the same spin arrangement direction as that of the first material layer 110a. As a result, the first conductive interconnection (102a in FIG. 1), the metal interconnection (112 in FIG. 1) and the second conductive interconnection (102b in FIG. 1) become electrically connected.

As shown in FIG. 3, when the reverse bias is applied to the magnetic fuse 110, the first material layer 110a has a spin arrangement in the first direction and the second material layer 110c has a spin arrangement in a direction that is opposite to that of the first material layer 110a. Consequently, resistance of the magnetic fuse 110 increases so that it is difficult for current to flow through the magnetic fuse 110. As a result, the first conductive interconnection (102a in FIG. 1) and the metal interconnection (112 in FIG. 1) are electrically insulated.

Here, reverse bias means a voltage having an opposite polarity to the forward bias. That is, a bias applied to each of the first conductive interconnection (102a in FIG. 1) and the second conductive interconnection (102b in FIG. 1) has a polarity that is opposite to a bias applied to the metal interconnection (112 in FIG. 1).

As described above, the same effect obtained by fuse cutting can be obtained by simply applying a reverse bias to the magnetic fuse to electrically insulate the metal interconnection and the conductive interconnection without using a conventional method of physically cutting a fuse by radiating a laser to the fuse in order to replace a failed memory cell with a normal memory cell.

That is, in the exemplary embodiment, since the conventional method of physically cutting a fuse by radiating a laser to the fuse is not used, failure that may be caused by a laser mistakenly radiated can be prevented. For example, a failure caused by radiating a laser to an undesired location, such as a periphery of a target fuse, or a failure caused by incomplete cutting can be prevented.

The above embodiment of the present invention is illustrative and not limitative. Various alternatives and equivalents are possible. The invention is not limited by the embodiment described herein. Nor is the invention limited to any specific type of semiconductor device. Other additions, subtractions, or modifications are obvious in view of the present disclosure and are intended to fall within the scope of the appended claims.

The present invention includes the following features.

1. A method of repairing a semiconductor device, comprising:

forming a first conductive interconnection and a second conductive interconnection that is spaced apart from the first conductive interconnection over a semiconductor substrate;

forming a magnetic fuse over the first conductive interconnection and forming a first contact plug over the second conductive interconnection;

forming a metal interconnection over the magnetic fuse and the first contact plug; and

applying a bias to the first conductive interconnection or to the second conductive interconnection corresponding to a normal cell or a redundancy cell and the metal interconnection.

2. The method of claim 1, wherein, when the first conductive interconnection is coupled to the normal cell, the second conductive interconnection is coupled to the redundancy cell, and

wherein, when the first conductive interconnection is coupled to the redundancy cell, the second conductive interconnection is coupled to the is normal cell.

3. The method of claim 1, wherein the magnetic fuse includes:

a first material layer having a spin arrangement in a first direction;

a barrier layer disposed over the first material layer; and

a second material layer disposed over the barrier layer and having a spin arrangement in the first direction or in a second direction opposite to the first direction, depending on an applied bias.

4. The method of claim 3, wherein the bias includes a forward bias or a reverse bias.

5. The method of claim 4, wherein, when the forward bias is applied, the second material layer has the spin arrangement in the first direction.

6. The method of claim 5, wherein the forward bias is applied when the normal cell is a non-failed cell.

7. The method of claim 4, wherein, when the reverse bias is applied, the second material layer has the spin arrangement in the second direction.

8. The method of claim 7, wherein the reverse bias is applied when the normal cell is a failed cell.

9. The method of claim 4, wherein the reverse bias has an opposite polarity to the forward bias.

10. The method of claim 3, wherein the first material layer includes any selected from the group consisting of IrMn, PtMn, MnO, MnS, MnTe, MnF₂, FeF₂, FeCl₂, FeO, CoCl₂, CoO, NiCl₂, NiO and a combination thereof.

11. The method of claim 3, wherein the second material layer includes any one selected from the group consisting of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, MgOFe₂O₃, EuO, Y₃Fe₅O₁₂ and a combination thereof.

13. The method of claim 3, wherein the barrier layer includes an insulating layer.

14. The method of claim 13, wherein the insulating layer is formed to such a thickness that electrons can penetrate the insulating layer.

15. The method of claim 1, wherein the first conductive interconnection and the second conductive interconnection includes a bit line.

16. The method of claim 1, the method further comprising forming a second contact plug over the first conductive interconnection.

17. A method of repairing a semiconductor device, comprising:

(i) providing a semiconductor device, wherein the semiconductor comprising:
a first conductive interconnection and a second conductive interconnection which are insulated from each other;
a magnetic fuse coupled to the first conductive interconnection;
a contact plug coupled to the second conductive interconnection; and
a third conductive interconnection commonly coupled to the magnetic fuse and the contact plug,
wherein the magnetic fuse includes:
   a first magnetic layer configured to have a first spin arrangement; and
   a second magnetic layer formed over or below the first magnetic layer and configured to have the first spin arrangement when a forward bias is applied between the first conductive interconnection and the third conductive interconnection, and further configured to have a second spin arrangement different from the first spin arrangement when a reverse bias is applied between the first conductive interconnection and the third conductive interconnection,

(ii) determining whether there is a failure in the first conductive interconnection,

(iii) applying a forward bias between the first conductive interconnection and the third conductive interconnection so that the first conductive interconnection and the third conductive interconnection are coupled to each other by the second magnetic layer, in case there is no failure in the first conductive interconnection, and

(iv) applying a reverse bias between the first conductive interconnection and the third conductive interconnection so that the first conductive interconnection and the third conductive interconnection are insulated by the second magnetic layer, and instead, the second conductive interconnection and the third conductive interconnection are coupled to each other, in case there is a failure in the first conductive interconnection.

What is claimed is:

1. A semiconductor device, comprising:
a first conductive interconnection and a second conductive interconnection that is spaced apart from the first conductive interconnection disposed over a semiconductor substrate;
a magnetic fuse disposed over the first conductive interconnection;
a contact plug disposed over the second conductive interconnection; and
a metal interconnection disposed over the magnetic fuse and the contact plug,
wherein the magnetic fuse includes:
a first material layer having a spin arrangement in a first direction;
is a barrier layer disposed over the first material layer; and
a second material layer disposed over the barrier layer and having a spin arrangement in the first direction or in a second direction opposite to the first direction, depending on an applied bias.

2. The semiconductor device of claim 1, wherein the applied bias includes a forward bias or a reverse bias.

3. The semiconductor device of claim 2, wherein, when the forward bias is applied, the second material layer has the spin arrangement in the first direction.

4. The semiconductor device of claim 3, wherein the forward bias is applied when the normal cell is a non-failed cell.

5. The semiconductor device of claim 2, wherein, when the reverse bias is applied, the second material layer has the spin arrangement in the second direction.

6. The semiconductor device of claim 5, wherein the reverse bias is applied when the normal cell is a failed cell.

7. The semiconductor device of claim 2, wherein the reverse bias has an opposite polarity to the forward bias.

8. The semiconductor device of claim 1, wherein the first material layer includes any selected from the group consisting of IrMn, PtMn, MnO, MnS, MnTe, MnF₂, FeF₂, FeCl₂, FeO, CoCl₂, CoO, NiCl₂, NiO and a combination thereof.

9. The semiconductor device of claim 1, wherein the second material layer includes any one selected from the group consisting of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, MgOFe₂O₃, EuO, Y₃Fe₅O₁₂ and a combination thereof.

10. The semiconductor device of claim 1, wherein the barrier layer includes an insulating layer formed to such a thickness that electrons can penetrate the insulating layer.

11. A semiconductor device comprising:
a first conductive interconnection and a second conductive interconnection which are insulated from each other;
a magnetic fuse coupled to the first conductive interconnection;
a contact plug coupled to the second conductive interconnection; and
a third conductive interconnection commonly coupled to the magnetic fuse and the contact plug,
wherein the magnetic fuse includes:
a first magnetic layer configured to have a first spin arrangement; and
a second magnetic layer formed over or below the first magnetic layer and configured to have the first spin arrangement when a forward bias is applied between the first conductive interconnection and the third conductive interconnection, and further configured to have a second spin arrangement different from the first spin arrangement when a reverse bias is applied between the first conductive interconnection and the third conductive interconnection.

12. The semiconductor device of claim 11, wherein at the forward bias, the second magnetic layer is configured to have the first spin arrangement so that the first conductive interconnection and the third conductive interconnection are coupled to each other through the magnetic fuse, and
wherein, at the reverse bias, the second magnetic layer is configured to have the second spin arrangement so that the first conductive interconnection and the third conductive interconnection are insulated from each other by the magnetic fuse.

13. The semiconductor device of claim 12, the device further comprising;
a barrier layer disposed over the first magnetic layer,
wherein the second magnetic layer disposed over the barrier layer.

14. The semiconductor device of claim 1, wherein the first magnetic layer includes any selected from the group consisting of IrMn, PtMn, MnO, MnS, MnTe, MnF₂, FeF₂, FeCl₂, FeO, CoCl₂, CoO, NiCl₂, NiO and a combination thereof.

15. The semiconductor device of claim 1, wherein the second magnetic layer includes any selected from the group consisting of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, MgOFe₂O₃, EuO, Y₃Fe₅O₁₂ and a combination thereof.

16. The semiconductor device of claim 13, wherein the barrier layer includes an insulating layer formed to such a thickness that electrons can penetrate the insulating layer.
